(19) United States
(12) Patent Application Publication
(10) Pub. No.: US 2006/0189009 A1
(43) Pub. Date: Aug. 24, 2006

(54) Apparatus for controlling semiconductor manufacturing process

(75) Inventors: Byung-Bok Ahn, Seoul (KR); Tae-Jin Yun, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/360,300

(22) Filed: Feb. 22, 2006

(30) Foreign Application Priority Data
Feb. 23, 2005 (KR) 10-2005-0015039

(51) Int. Cl. H01L 21/66; H01L 23/58; H01L 21/20

(52) U.S. Cl. 438/14; 438/385; 257/48

(57) ABSTRACT

An apparatus for controlling a semiconductor manufacturing process includes, a filter which receives from semiconductor processing devices first process parameters for processing a wafer and measured data obtained by measuring the wafer, and removes noise from the first process parameters and the measured data, a model generating unit which receives the first process parameters and the measured data from the filter and generates process models for predicting results of processing the wafer, a model selecting unit which selects a process model suitable for processing the wafer from a plurality of the process models stored in the model generating unit according to a received request, a process predicting unit which receives second process parameters for processing the wafer from the semiconductor processing devices, requests and receives the process model to and from the model selecting unit, and predicts a result of processing the wafer using the received process model, and a process controlling unit which receives the predicted result from the process predicting unit and controls the operations of the semiconductor processing devices.

### CROSS-REFERENCE TO RELATED PATENT APPLICATION

This application claims priority to Korean Patent Application No. 10-2005-0015039, filed on Feb. 23, 2005, the disclosure of which is incorporated herein in its entirety by reference.

### BACKGROUND OF THE INVENTION

1. Technical Field

The present disclosure relates to an apparatus for controlling a semiconductor manufacturing process, and more particularly, to an apparatus which predicts the result of processing a wafer and controls semiconductor processing devices.

2. Discussion of the Related Art

Semiconductor devices are manufactured in a wafer in several processes. In each process, the wafer is subjected to several operations. After each process is finished, the wafer is measured using a different measuring device for each process to determine whether the wafer is good or bad. A bad wafer such as, for example, a wafer that is faulty, or unable to properly perform its designated function, is discarded, and a good wafer is used for the next process. After the entire process for the wafer is completed, the yield of the semiconductor devices manufactured in the wafer is measured. For a wafer having bad semiconductor devices, it is determined which process generated the failure of semiconductor devices and the respective process equipment is reset using a preventive maintenance (PM) process or a cleaning process.

To reduce the manufacturing time of the wafer, the time-consuming measuring operations for each process may be omitted. As a result, the bad semiconductor devices are detected after the entire process for the wafer is completed by checking the yield of the semiconductor devices. However, if the bad semiconductor devices are detected after the entire process for the wafer is completed, the completed bad wafer must be discarded. As a result, the manufacturing cost increases. Also, since the process which caused the failure of the semiconductor devices must be determined, the time for producing the wafer increases.

### SUMMARY OF THE INVENTION

According to an embodiment of the present invention, an apparatus for controlling a semiconductor manufacturing process comprises a filter which receives from semiconductor processing devices first process parameters for processing a wafer and measured data obtained by measuring the wafer, and removes noise from the first process parameters and the measured data, a model generating unit which receives the first process parameters and the measured data from the filter and generates process models for predicting results of processing the wafer, a model selecting unit which selects a process model suitable for processing the wafer from a plurality of the process models stored in the model generating unit according to a received request, a process predicting unit which receives the process parameters for processing the specific wafer from the semiconductor processing devices, requests and receives the process model from the model selecting unit, and predicts a result of processing the wafer using the received process model; and a process controlling unit which receives the predicted result from the process predicting unit and controls the operations of the semiconductor processing devices.

The filter may normalize and analyze the process parameters and the measured data.

The model generating unit may generate the process models using a non-iteration method and may predict the result of processing a wafer using the equation Y′=X×P×M×Q′, where X denotes a first process parameter vector, P denotes the loading vector of the first process parameter, M denotes a matrix, and Q′ denotes the transpose of a loading vector of the measured data.

The matrix is for mapping X and Y, where Y is the measured data defined by the equation Y=U×Q′+F where U denotes a score vector of the measured data and F denotes an error of the measured data.

The process controlling unit may issue an alert and change the second process parameters of the semiconductor processing devices or stop the operations of the semiconductor processing devices, if it is determined that the wafer is bad.

The filter may receive the first process parameters and the measured data and the process predicting unit may receive the second process parameters transmitted from the semiconductor processing devices through a controller.

The apparatus may further include a model database connected to the model generating unit, wherein the model database receives and stores the process models from the model generating unit.

### BRIEF DESCRIPTION OF THE DRAWINGS

Exemplary embodiments of the present invention can be understood in more detail from the following description taken in conjunction with the accompanying drawings in which:

FIG. 1 is a block diagram of a semiconductor process controlling apparatus and peripheral devices connected thereto according to an embodiment of the present invention;

FIG. 2 is a block diagram of the semiconductor process controlling apparatus illustrated in FIG. 1 according to an embodiment of the present invention;

FIG. 3 is a flowchart illustrating a process model generating method used by the semiconductor process controlling apparatus illustrated in FIG. 1 according to an embodiment of the present invention;

FIG. 4 is a flowchart illustrating a process controlling method used by the semiconductor process controlling apparatus illustrated in FIG. 1 according to an embodiment of the present invention; and

FIG. 5 is a graph for comparing predicted values of a wafer to be manufactured and actually measured values after the wafer manufacturing process is completed.

### DETAILED DESCRIPTION OF THE EXEMPLARY EMBODIMENTS

Exemplary embodiments of the present invention are more fully described below with reference to the accompanying drawings. The present invention may be embodied in many different forms and should not be construed as being limited to the embodiments set forth herein.

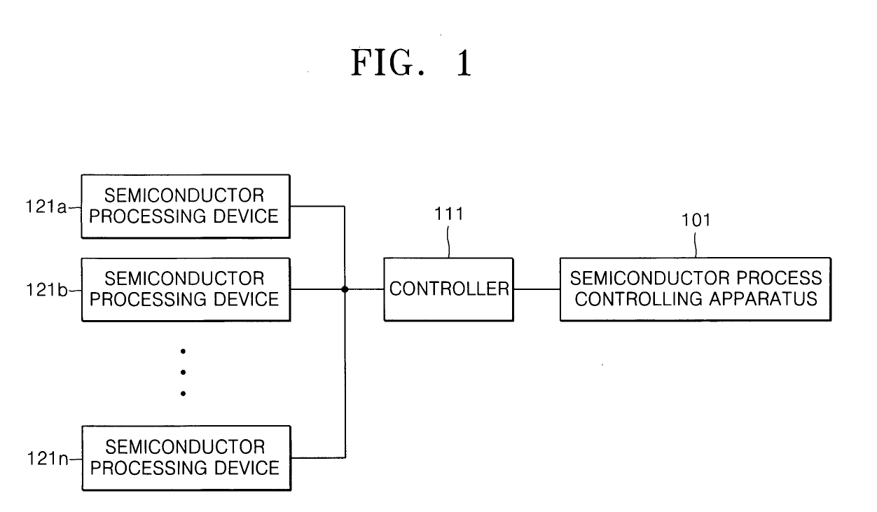

FIG. 1 is a block diagram of a semiconductor process controlling apparatus 101 and peripheral devices connected thereto according to an embodiment of the present invention. The semiconductor manufacturing process controlling apparatus 101 is connected to a controller 111 which is connected to a plurality of semiconductor processing devices 121a˜121n.

The semiconductor processing devices 121a˜121n are used to manufacture semiconductor devices in a wafer and are used to measure, for example, chemical, mechanical and/or electrical properties of the manufactured semiconductor devices. Semiconductor processes performed with the semiconductor processing devices 121a˜121n generally include, for example, a diffusion process, a photolithography process, an etching process, a sputtering process, a chemical vapor deposition (CVD) process, an implanting process, a chemical and mechanical polishing (CMP) process, and a cleaning process. The semiconductor processing devices 121a˜121n include, for example, an etcher, a lithographer, and a scanning electron microscope (SEM).

The controller 111 controls the semiconductor processing devices 121a˜121n, receives data from the semiconductor processing devices 121a˜121n, and transmits the received data to the semiconductor process controlling apparatus 101. That is, the controller 111 receives data such as process parameters, preventive maintenance (PM) time, and environment variables from the semiconductor processing devices 121a˜121n, transmits the received data to the semiconductor process controlling apparatus 101, and controls the semiconductor processing devices 121a˜121n in response to commands received from the semiconductor process controlling apparatus 101. If the semiconductor processing devices 121a˜121n are operated manually, the controller 111 can be omitted.

The semiconductor process controlling apparatus 101 receives the process parameters and measured data from the controller 111, generates process models, and stores the process models. When the semiconductor processing devices 121a˜121n perform the processes for manufacturing the semiconductor devices in the wafer, the semiconductor process controlling apparatus 101 receives the process parameters through the controller 111, predicts semiconductor processing results, and controls the semiconductor processing devices 121a˜121n according to the predicted semiconductor processing results.

The semiconductor process controlling apparatus 101 may be included in an equipment engineering system (EES) for establishing an application module such as, for example, fault detection and classification (FDC), advanced process control (APC), or recipe management module (RMM).

The semiconductor process controlling apparatus 101 may control the semiconductor processing devices 121a˜121n using a controlling method such as, for example, a proportional integral (PI) method, a proportional derivative (PD) method, a proportional integral and derivative (PID) method, a model predictive control(MPC) method, or a modified partial least square (PLS) control method.

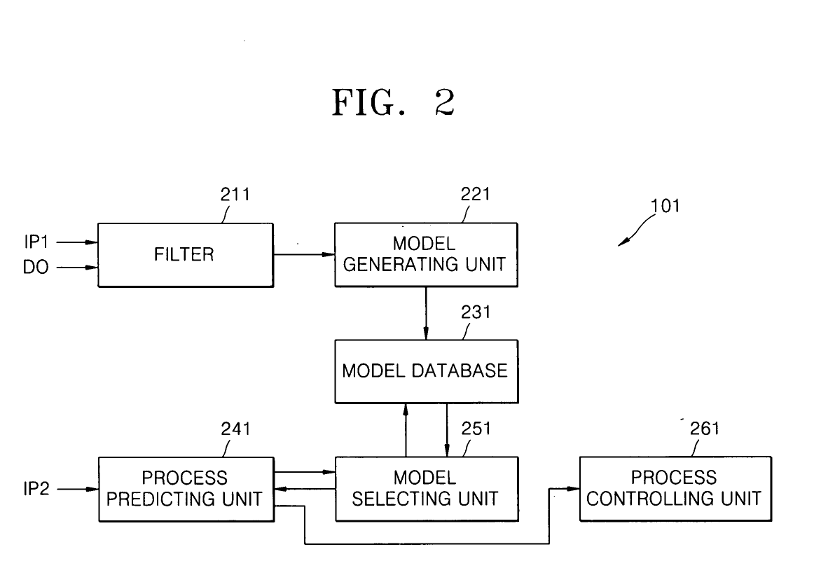

The semiconductor process controlling apparatus 101 is further described with reference to FIG. 2.

FIG. 2 is a block diagram of the semiconductor process controlling apparatus 101 illustrated in FIG. 1 according to an embodiment of the present invention. The semiconductor process controlling apparatus 101 includes a filter 211, a model generating unit 221, a model database 231, a model selecting unit 251, a process predicting unit 241, and a process controlling unit 261.

The filter 211 receives process parameters IP1 used to manufacture the semiconductor devices and measured data D0 of the manufactured semiconductor devices from the semiconductor processing devices 121a˜121n, removes noise included in the process parameters IP1 and the measured data D0, and normalizes and analyzes the process parameters IP1 and the measured data D0.

The model generating unit 221 receives the process parameters IP1 and the measured data D0 from the filter 211 and generates process models for predicting the result of processing the wafer.

The model database 231 is connected to the model generating unit 221, receives the process models from the model generating unit 221, and stores the process models. In an embodiment of the present invention, the model database 231 may be included in the model generating unit 221.

The model selecting unit 251 selects a process model suitable for processing a specific wafer from a plurality of the process models stored in the model generating unit 221 according to the request of the process predicting unit 241.

The process predicting unit 241 receives process parameters IP2 for processing the specific wafer from the semiconductor processing devices 121a˜121n, requests and receives the process model from the model selecting unit 251, and predicts the result of processing the specific wafer using the received process model.

The process controlling unit 261 receives the predicted value from the process predicting unit 241 and controls the semiconductor processing devices 121a˜121n. That is, if the process controlling unit 261 determines that the wafer is bad by analyzing the predicted value, the process controlling unit 261 stops the operation of the semiconductor processing devices 121a˜121n and sends an alert to an operator operating the semiconductor processing devices 121a˜121n. The process controlling unit 261 may control the semiconductor processing devices 121a˜121n by a method such as, for example, the PI method, the PD method, the PID method, the MPC method, or the modified PLS method.

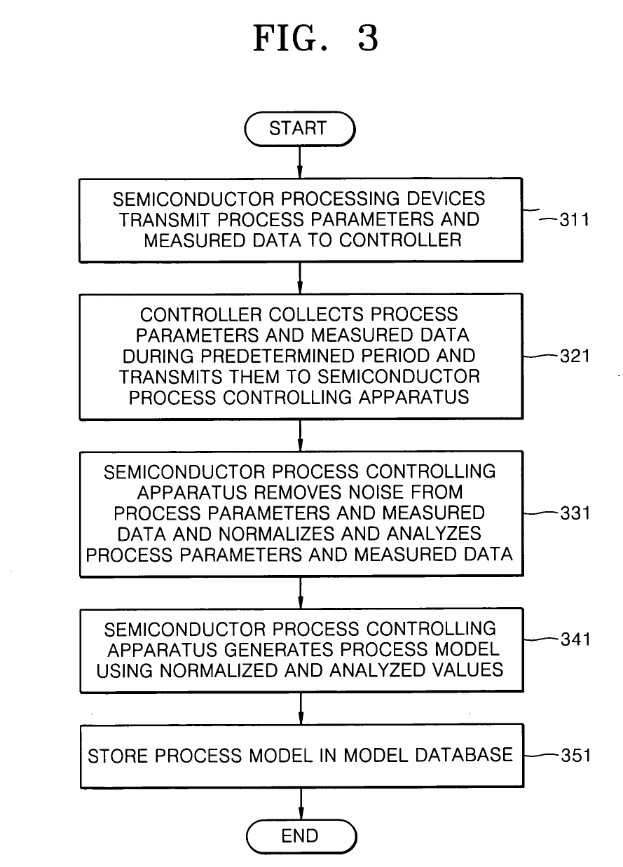

FIG. 3 is a flowchart illustrating a process model generating method used by the semiconductor process controlling apparatus 101 illustrated in FIG. 1 according to an embodiment of the present invention. The process model generating method will now be described with reference to FIGS. 1, 2 and 3.

In operation 311, the semiconductor processing devices 121a˜121n are used to manufacture a plurality of wafers and transmit the process parameters IP1 and the measured data D0 to the controller 111.

In operation 321, the controller 111 collects the process parameters IP1 and the measured data D0 for a predetermined time period and transmits the process parameters IP1 and the measured data D0 to the semiconductor process controlling apparatus 101.

In operation 331, the semiconductor process controlling apparatus 101 removes noise from the received process parameters IP1 and the measured data D0. That is, the semiconductor process controlling apparatus 101 normalizes and analyzes the process parameters IP1 and the measured data D0, and if noise is found in the analyzed result, the semiconductor process controlling apparatus 101 removes the noise from the received process parameters IP1 and the measured data D0 and then normalizes and analyzes the process parameters IP1 and the measured data D0 again.

The process of normalizing and analyzing the process parameters IP1 will now be described.

A process parameter vector (x) may include, for example, a gas flow rate read from a mass flow controller, a temperature read from a thermal sensor, and a pressure read from a pressure gauge. At a certain instant of time, which can be set by a user, the process parameter vector (x) may be [10 50 15], where the measuring units of the gas flow rate, temperature, and pressure respectively are, for example, [sccm], [° C.] and [psi]. If the data are collected for a predetermined period, m sets of data can be collected. If the number of the measured variables is n, an m*n matrix is formed. However, since the measured variables can be expressed using different measuring units, the data can be substantially varied depending on the measuring units. For example, 14.7 [psi] can also be represented by 1 [atm] or 1.014 [kPa]. Thus, because of the variation in measuring units, the obtained process parameter vector is not used, and must be normalized. Also, a method of analyzing the vector components based on the variables having the largest correlation therebetween must be used.

Accordingly, the process parameter vector must be normalized. When an average and a standard deviation are calculated from the data collected during the predetermined period and the normalization is performed as shown by Equation 1, data become non-dimensional and normalization values such as an average value of 0 and a standard deviation of 1 can be obtained.

If the i-th vector component of x is xi, the normalization value (zi) is expressed by Equation 1.
zi=(xi−average of xi)/(standard deviation of xi) [Equation 1]

Here, the average and the standard deviation of xi are expressed by Equations 2 and 3.

$$\begin{matrix}average of xi = \frac{\sum xi}{m} & [ Equation 2 ] \\ \begin{matrix}standard deviation \\ of xi\end{matrix} = \frac{\sum {( xi - average of xi )}^{2}}{m - 1} & [ Eqaution 3 ]\end{matrix}$$

By dividing the standard deviation of xi by (m−1), a sampled standard deviation is obtained. When sampling is well performed, the sampled standard deviation is close to a normal distribution. For this, unbiased sampling must be performed using the value (m−1).

If the normalized m*n matrix is X, X is analyzed as shown by Equation 4.
X=T×P′+E [Equation 4]

Here, T denotes the score vector of the process parameter vector X, P denotes the loading vector of the process parameter vector X, E denotes the error of the process parameter vector X, and P′ denotes the transpose of P.

If X is analyzed as mentioned above, the loading vector (P) is transformed into a new coordinate system using the correlation of X, and thus the coordinate-transformed score vector (T) can be used. If the matrix X is transformed as mentioned above, the error (E) is generated. In an embodiment of the present invention, the threshold value of the error (E) is set to 0.001, and a modeling can be performed only when the error (E) is less than 0.001.

In order to remove noise such as, for example, hunting, generated due to the mixture of data or the temporary failure of a sensor, a multi-dimensional space distance is calculated using the score vector (T), which is already formed in an orthogonal coordinate system, and it is determined whether abnormal points exists in the multi-dimensional space distance by calculating the contribution of each parameter in the score vector (T) and checking whether the parameter having a highest contribution is changed in the modeling period. If the abnormal point, that is, noise, is found, the abnormal point is removed and the process parameter is normalized and analyzed using Equations 1 through 4.

To remove noise included in the measured data D0, the measured data D0 is also normalized and analyzed using the above-mentioned method as shown by Equation 5.
Y=U×Q′+F [Equation 5]

Here, Y is a measured data vector, U denotes the score vector of the measured data, Q denotes the loading vector of the measured data, Q′ denotes the transpose of Q, and F denotes the error of the measured data D0.

For example, it is assumed that the process parameters received from the semiconductor process controlling apparatus 101 are as shown in Table 1.

TABLE 1

| GAS FLOW RATE | TEMPERATURE | PRESSURE |
|---|---|---|
| 5 | 6 | 7 |
| 2 | 3 | 4 |
| 1 | 5 | 3 |
| 3 | 2 | 2 |

By normalizing the process parameters using Equations 1-3, matrix, X is obtained as shown in Table 2.

TABLE 2

| | | |
|---|---|---|
| 1.317465 | 1.095445 | 1.38873 |
| −0.43916 | −0.54772 | 0 |
| −1.0247 | 0.547723 | −0.46291 |
| 0.146385 | −1.09545 | −0.92582 |

By transforming matrix X into an orthogonal coordinate system according Equation 4 and analyzing it, the score vector (T) of the process parameters is obtained as shown in Table 3.

TABLE 3

| | | |
|---|---|---|
| −2.1972 | 0.1838 | 0.0518 |
| 0.5302 | 0.0549 | −0.4569 |
| 0.5449 | −1.1128 | 0.1704 |
| 1.1222 | 0.8742 | 0.2347 |

The loading vector (P) of the process parameters is obtained as shown in Table 4.

TABLE 4

| | | |
|---|---|---|
| −0.5284 | 0.7288 | 0.4355 |
| −0.5444 | −0.6845 | 0.4849 |
| −0.6515 | −0.0191 | −0.7584 |

The error (E) is obtained as shown in Table 5.

TABLE 5

| | | |
|---|---|---|
| 0 | 0 | 0 |
| 0 | 0 | 0 |
| 0 | 0 | 0 |
| 0 | 0 | 0 |

Since all the components of the error (E) are less than 0.001, which is the threshold value, Equation 4 is expressed by (X=T×P′). The analyzed result of the process parameter is obtained as shown in Table 6.

TABLE 6

| | | |
|---|---|---|
| 1.317465 | 1.095445 | 1.38873 |
| −0.43916 | −0.54772 | 0 |
| −1.0247 | 0.547723 | −0.46291 |
| 0.146385 | −1.09545 | −0.92582 |

Next, for example, it is assumed that the measured data D0 received from the semiconductor process controlling apparatus 101 is as shown in Table 7.

TABLE 7

| THICKNESS | WIDTH |
|---|---|
| 1 | 2 |
| 2 | 3 |
| 1 | 4 |
| 3 | 2 |

By normalizing the measured data, Y is obtained as shown in Table 8.

TABLE 8

| | |
|---|---|
| −0.78335 | −0.78335 |
| 0.261116 | 0.261116 |
| −0.78335 | 1.305582 |
| 1.305582 | −0.78335 |

By transforming Y into an orthogonal coordinate system according to Equation analyzing it, the score vector (U) of the measured data is obtained as shown in 9.

TABLE 9

| | |
|---|---|
| 0 | 1.1078 |
| 0 | −0.3693 |
| −1.4771 | −0.3693 |
| 1.4771 | −0.3693 |

The loading vector (Q) of the measured data is obtained as shown in Table 10.

TABLE 10

| | |
|---|---|
| 0.7071 | −0.7071 |
| −0.7071 | −0.7071 |

In operation 341, the process model is generated using X and Y as shown in Equation 6.
Y′=X×P×M×Q′
[Equation 6]

Here, X denotes the process parameter vector, P denotes the loading vector of the process parameter vector, M denotes a matrix for mapping X of Equation 4 and Y of Equation 5, and Q′ denotes the transpose of the loading vector of the measured data D0.

The process model obtained using X and Y according to Equation 6 is shown in Table 11.

TABLE 11

| | |
|---|---|
| −0.78335 | −0.78335 |
| 0.261116 | 0.261116 |
| −0.78335 | 1.305582 |
| 1.305582 | −0.78335 |

As mentioned above, the process model expressed by Equation 5 can be obtained by the modified PLS method or using a non-iteration method.

In operation 351, the process model is stored in the model database 231.

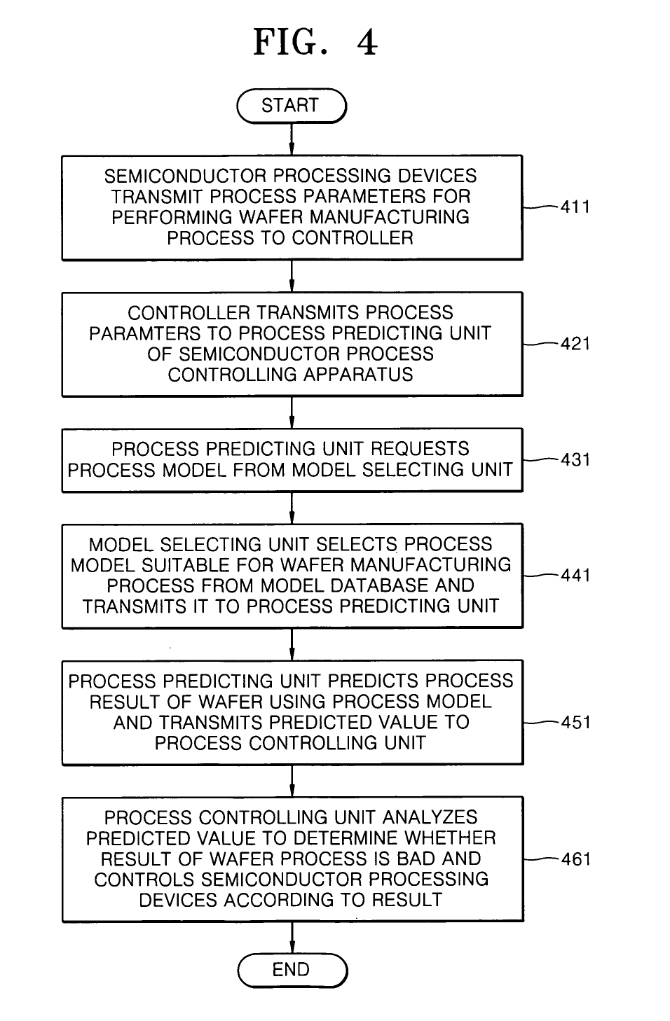

FIG. 4 is a flowchart illustrating a process controlling method used by the semiconductor process controlling apparatus 101 illustrated in FIG. 1 according to an embodiment of the present invention. The process controlling method will now be described with reference to FIGS. 1, 2 and 4.

In operation 411, the semiconductor processing devices 121a˜121n transmit to the controller 111 the process parameters IP2 for manufacturing semiconductor devices in a wafer.

In operation 421, the controller 111 transmits the process parameters IP2 to the process predicting unit 241.

In operation 431, the process predicting unit 241 requests the process model from the model selecting unit 251.

In operation 441, the model selecting unit 251 selects a suitable process model from the process models in the model database 231 using the process parameters IP2 and transmits the suitable process model to the process predicting unit 241.

In operation 451, the process predicting unit 241 predicts the result of manufacturing the wafer using the suitable process model such as, for example, Equation 6. For example, it is assumed that the normalized value of the process parameter is as shown in Table 12.

TABLE 12

| | | |
|---|---|---|
| −1.0247 | 0.547723 | −0.46291 |

If the predicted value is calculated by substituting the values in Table 12 in (X) in Equation 6, the predicted value is obtained as shown in Table 13.

TABLE 13

| | |
|---|---|
| −0.78335 | 1.305582 |

As shown in Table 13, the predicted measured data matches the data shown in Table 11.

Before the process of manufacturing the semiconductor devices in the wafer is performed, the process predicting unit 241 can predict, by using the process parameters IP2, the data value which will be measured after the wafer is completed.

In operation 461, the process controlling unit 261 receives the predicted value from the process predicting unit 241 and determines whether the wafer is bad or good. That is, the process controlling unit 261 determines that the wafer is good if the predicted value is in a predetermined range. The predetermined range can be determined by, for example, a conventional single response method.

The process controlling unit 261 issues an alert to an operator and stops the operations of the semiconductor processing devices 121a˜121n, if it is determined that the wafer is bad.

Using the predicted value, the process controlling unit 261 changes the process parameters IP2 of the semiconductor processing devices 121a˜121n. The matrix M for mapping X of Equation 4 and Y of Equation 5 has information to determine which vector parameters, among the score vector (T of Equation 3) for transforming the process parameter vector into the orthogonal coordinate system and the score vector (U of Equation 4) for transforming the measured data vector into the orthogonal coordinate system, most influence the semiconductor processing devices 121a˜121n. The process controlling unit 261 can change the process parameters in descending influence order based on this information. The method used can be the PID method, the PD method, the modified PLS (e.g., Equation 6) method, and the MPC method. The operator can select a desired method and adjust the variable such that the semiconductor process controlling apparatus 101 changes the process parameters.

The number of the variables for controlling the semiconductor processing devices 121a˜121n can be one or more. If the number of the variables is one, the semiconductor processing devices 121a˜121n must be maintained to become a same value using the MPC method, the PID method, or the PD method. If there is more than one variable, the semiconductor processing devices 121a˜121n can be adjusted using the modified PLS (e.g., Equation 6) method.

According to an embodiment of the present invention, the process controlling unit 261 prepares a table or a graph of the predicted values, which can be conveniently used by the operator, and may output the table or the graph in a screen or printer format such that the operator can monitor the state of the operation of the model generating unit 221 and the process controlling unit 261.

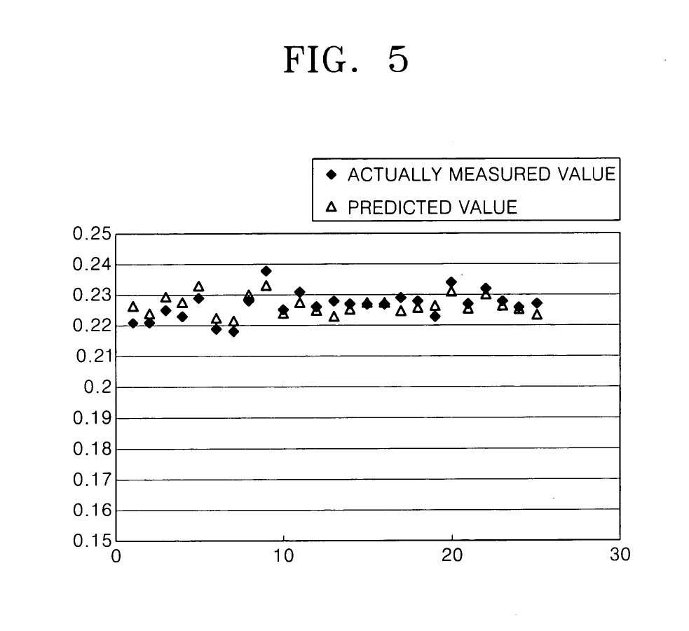

FIG. 5 is a graph for comparing the predicted values of a wafer to be manufactured and actually measured values after the wafer manufacturing process is completed. The X axis represents the number of wafers. The Y axis represents a critical dimension measuring a width of gate-poly of a MOS transistor. The unit of the critical dimension is micrometers (μm). As shown in FIG. 5, it can be seen that the predicted values are similar to the actually measured values.

According to the embodiments of the present invention, the result of manufacturing the wafer is predicted before the process of manufacturing the semiconductor devices in a wafer is performed and the operations of the semiconductor processing devices 121a˜121n are suitably controlled if it is determined that the wafer will be bad. Accordingly, the number of the bad wafers can be reduced and thus the yield of the semiconductor devices can be improved.

Also, according to embodiments of the present invention, the number of the process condition experiments performed can be minimized and the number of the processes of measuring the semiconductor processing devices 121a˜121n can be reduced. Accordingly, the time and the cost for manufacturing the wafer can be reduced.

Although preferred embodiments have been described with reference to the accompanying drawings, it is to be understood that the present invention is not limited to these precise embodiments but various changes and modifications can be made by one skilled in the art without departing from the spirit and scope of the present invention. All such changes and modifications are intended to be included within the scope of the invention as defined by the appended claims.

What is claimed is:

1. An apparatus for controlling a semiconductor manufacturing process, comprising:
a filter which receives from semiconductor processing devices first process parameters for processing a wafer and measured data obtained by measuring the wafer, and removes noise from the first process parameters and the measured data;
a model generating unit which receives the first process parameters and the measured data from the filter and generates process models for predicting results of processing the wafer;
a model selecting unit which selects a process model suitable for processing the wafer from a plurality of the process models stored in the model generating unit according to a received request;
a process predicting unit which receives second process parameters for processing the wafer from the semiconductor processing devices, requests and receives the process model from the model selecting unit, and predicts a result of processing the wafer using the received process model; and
a process controlling unit which receives the predicted result from the process predicting unit and controls operations of the semiconductor processing devices.

2. The apparatus according to claim 1, further comprising a model database connected to the model generating unit, wherein the model database receives and stores the process models from the model generating unit.

3. The apparatus according to claim 1, wherein the filter normalizes and analyzes the first process parameters and the measured data.

4. The apparatus according to claim 1, wherein the model generating unit generates the process models using a non-iteration method.

5. The apparatus according to claim 1, wherein the model generating unit predicts the result of processing a wafer using the equation
Y′=X×P×M×Q′
where X denotes a first process parameter, P denotes a loading vector of the first process parameter, M denotes a matrix, and Q′ denotes the transpose of a loading vector of the measured data.

6. The apparatus according to claim 5, wherein the matrix is for mapping X and Y, where Y is the measured data defined by the equation Y=U×Q′+F where U denotes a score vector of the measured data and F denotes an error of the measured data.

7. The apparatus according to claim 1, wherein the process controlling unit issues an alert if it is determined that the wafer is bad.

8. The apparatus according to claim 1, wherein the process controlling unit stops the operations of the semiconductor processing devices if it is determined that the wafer is bad.

9. The apparatus according to claim 1, wherein the process controlling unit changes the second process parameters of the semiconductor processing devices if it is determined that the wafer is bad.

10. The apparatus according to claim 1, wherein the filter receives the first process parameter and the measured data and the process predicting unit receives the second process parameters transmitted from the semiconductor processing devices through a controller.

11. The apparatus according to claim 1, wherein the semiconductor processing devices include at least one of an etcher, a lithographer, or a scanning electron microscope.

12. An apparatus for generating a process model, comprising:
a plurality of semiconductor processing devices;
a controller, wherein the plurality of semiconductor processing devices transmit process parameters and measured data to the controller and the controller collects the process parameters and the measured data during a predetermined period; and
a semiconductor process controlling apparatus including a model generating unit and a model database, wherein:
the model generating unit receives the process parameters and the measured data from the controller; the model generating unit removes noise from the process parameters and the measured data; the model generating unit normalizes and analyzes the process parameters and the measured data; the model generating unit generates process models using the normalized and analyzed process parameters and measured data; and the model database stores the process models.

13. A method for controlling a semiconductor manufacturing process, comprising:
transmitting process parameters for performing a wafer manufacturing process to a controller;
transmitting the process parameters to a process predicting unit;
requesting a process model from a model selecting unit;
selecting a process model suitable for a wafer manufacturing process from a model database;
transmitting the selected process model to the process predicting unit;
predicting a process result of a wafer using the selected process model;
transmitting the predicted process result to a process controlling unit;
analyzing the predicted process result to determine whether the predicted process result is bad; and
controlling semiconductor processing devices based on the predicted process result.

14. The method of claim 13, wherein the process controlling unit controls the semiconductor processing devices using at least one of a proportional integral (PI), a proportional derivative (PD), a proportional integral derivative (PID), a model predictive control (MPC) method, or a modified partial least square (PLS) control method.
